(19) United States
(12) Patent Application Publication
(10) Pub. No.: US 2023/0233982 A1
(43) Pub. Date: Jul. 27, 2023

(54) GAS PROCESSING FURNACE AND EXHAUST GAS PROCESSING DEVICE IN WHICH SAME IS USED

(71) Applicant: KANKEN TECHNO CO., LTD., Kyoto (JP)

(72) Inventor: Hiroshi IMAMURA, Kyoto (JP)

(21) Appl. No.: 18/002,543

(22) PCT Filed: Jul. 7, 2020
(86) PCT No.: PCT/JP2020/026577

§ 371 Date: Dec. 20, 2022

(51) Int. Cl. B01D 53/00; B01D 53/18

(52) U.S. Cl. CPC B01D 53/005; B01D 53/185; H01L 21/67017

(57) ABSTRACT

A gas processing furnace according to the present invention includes: a heater body filled with an electric heating element; and a tubular gas passage passing through the heater body. The gas processing furnace includes: a block-like heater body extending in the up-down direction and filled with the electric heating element; gas passages passing through the heater body in the up-down direction, the gas passages being consecutively disposed or extended in the front-back direction, the gas passages being arranged so as to form a plurality of arrays parallel to each other in the right-left direction, in a plan view; and a headbox mounted at an upper end portion of the heater body and configured to allow the gas passages to communicate with each other via a communication space formed inside the headbox.

### TECHNICAL FIELD

The present invention relates to a gas processing furnace suitable for an abatement process of a hardly decomposable exhaust gas including, for example, perfluoro compounds (PFCs) or the like, and an exhaust gas processing device in which the gas processing furnace is used.

### BACKGROUND ART

At present, as an industrial process including processing and manufacturing products, a wide variety of processes are developed and performed, and types of gases (hereinafter, referred to as “processing-target exhaust gas”) exhausted through such a wide variety of industrial processes are also of a wide variety. Accordingly, various kinds of exhaust gas processing methods and exhaust gas processing devices are selectively used according to the type of processing-target exhaust gas exhausted through the industrial process.

Among these, an electrothermal oxidative decomposition type exhaust gas processing method using an electric heater is the most prevalent decomposition processing method at present as an exhaust gas processing method in semiconductor manufacturing processes, allows processing steps to be easily controlled in decomposition of a processing-target exhaust gas (abatement-target gas), and allows the processing-target exhaust gas to be safely decomposed. In particular, an exhaust gas processing device in which wet scrubbers are disposed in front and to the back of a thermal decomposition device (gas processing furnace) using an electric heater can abate any abatement-target component in the processing-target exhaust gas until the concentration of the component becomes a threshold limit value (TLV): an exposure limit or less, in accordance with a wide variety of conditions in semiconductor manufacturing (see, for example, Patent Literature 1).

### CITATION LIST

### Patent Literature

[PTL 1] Japanese Laid-Open Patent Publication No. H07-323211

### SUMMARY OF INVENTION

### Technical Problem

“The 2030 Agenda for Sustainable Development” was adopted in the United Nations Summit in September 2015. After that, various discussions and investigations about, for example, efficient use of energy in future have been conducted. Under these circumstances, regarding an exhaust gas processing device that includes the above conventional electrothermal oxidative decomposition type gas processing furnace and that consumes a relatively large amount of power as energy during heating, it is expected that the needs for energy saving or space saving are growing.

Therefore, a main object of the present invention is to provide a gas processing furnace that can be downsized and can reduce power consumption to achieve efficient use of energy while maintaining advantages of the conventional electrothermal oxidative decomposition type gas processing furnace as they are, and an exhaust gas processing device in which the gas processing furnace is used.

### Solution to Problem

In order to achieve the aforementioned object, the present invention is directed to a gas processing furnace having the following configuration, for example, as shown in FIG. 1.

Specifically, the gas processing furnace includes a heater body 12 filled with an electric heating element, and a tubular gas passage 14 passing through the heater body 12.

The present invention exhibits, for example, the following effects.

The gas processing furnace includes the heater body 12 filled with the electric heating element, and the tubular gas passage 14 passing through the heater body 12. Thus, heat generated by the electric heating element can be applied fully and sufficiently to the gas flowing in the gas passage 14, by setting a diameter and a length of the gas passage 14 according to a flow rate of a heat-treatment-target gas that flows in the gas passage 14. In addition, unlike a conventional gas processing furnace, the gas passage 14 is provided inside the heater body 12 without providing the heater body in the furnace, and the heater body 12 itself functions as a “furnace”, thereby remarkably reducing the overall size of the gas processing furnace.

The present invention can be, for example, configured as shown in FIGS. 2 and 3, based on the above-described gas processing furnace (in FIG. 1).

Specifically, the gas processing furnace includes: a block-like heater body 12 extending in the up-down direction and filled with an electric heating element; gas passages 14 passing through the heater body 12 in the up-down direction, the gas passages 14 being consecutively disposed or extended in the front-back direction, the gas passages 14 being arranged so as to form a plurality of arrays parallel to each other in the right-left direction, in a plan view; and a headbox 16 mounted at an upper end portion of the heater body 12 and configured to allow the gas passages 14 to communicate with each other via a communication space 16a formed inside the headbox 16.

The present invention exhibits, for example, the following effects.

The gas passages 14 passing through the heater body 12 in the up-down direction are arranged so as to form the plurality of arrays parallel to each other in the right-left direction, the gas passages 14 being consecutively disposed or extended in the front-back direction, in a plan view, and thus heat generated by the electric heating element can be sufficiently applied, without waste, to a processing-target gas flowing in each of such a large number of gas passages 14. In particular, when the gas passage 14 is formed as a narrow tube having a perfect circular shape in a plan view or in an elongated slit shape in a plan view, the effect is more remarkable. In addition, unlike the conventional gas processing furnace, the gas passage 14 is provided inside the heater body 12 without providing the heater body in the furnace, and the heater body 12 itself functions as a “furnace”, thereby remarkably reducing the overall size of the gas processing furnace.

In addition to the above configuration, dust eliminating means 18 for eliminating dust accumulated in the gas passages 14 is preferably provided in the present invention.

In this case, the gas passages 14 are prevented from being clogged due to dust brought by the processing-target gas or dust produced as a byproduct through heating process, thereby enabling continuous long operation.

The second aspect of the present invention is directed to an exhaust gas processing device in which the above-described gas processing furnace is used, and the exhaust gas processing device includes any one of the above-described gas processing furnaces, and at least one of an inlet scrubber 20 for previously washing, with liquid, a processing-target exhaust gas E to be introduced into the gas processing furnace and an outlet scrubber 22 for cooling an exhaust gas E thermally decomposed in the gas processing furnace and washing the exhaust gas E with liquid.

### Advantageous Effects of Invention

According to the present invention, unlike the conventional electrothermal oxidative decomposition type gas processing furnace the inside of which is heated by a heating means such as a heater, heating means itself is provided with the gas passages for heating gas. Therefore, the present invention can provide the gas processing furnace that can be downsized and can reduce power consumption to achieve efficient use of energy while maintaining advantages of the conventional electrothermal oxidative decomposition type gas processing furnace as they are, and the exhaust gas processing device in which the gas processing furnace is used.

### BRIEF DESCRIPTION OF DRAWINGS

FIG. 1 is a sectional view schematically showing the most basic configuration (first embodiment) of a gas processing furnace according to the present invention.

FIG. 2 schematically illustrates an exhaust gas processing device in which a gas processing furnace is used, according to a second embodiment of the present invention.

FIG. 3 is an end view (in which the internal structure is omitted) taken along a line X-X′ in FIG. 2.

FIG. 4 is an end view (in which the internal structure is omitted), taken along the horizontal direction, of a gas processing furnace according to another embodiment (third embodiment) of the present invention.

FIG. 5 is an end view (in which the internal structure is omitted), taken along the horizontal direction, of a gas processing furnace according to another embodiment (fourth embodiment) of the present invention.

### DESCRIPTION OF EMBODIMENTS

Hereinafter, embodiments of a gas processing furnace and an exhaust gas processing device in which the gas processing furnace is used, according to the present invention, will be described with reference to the drawings.

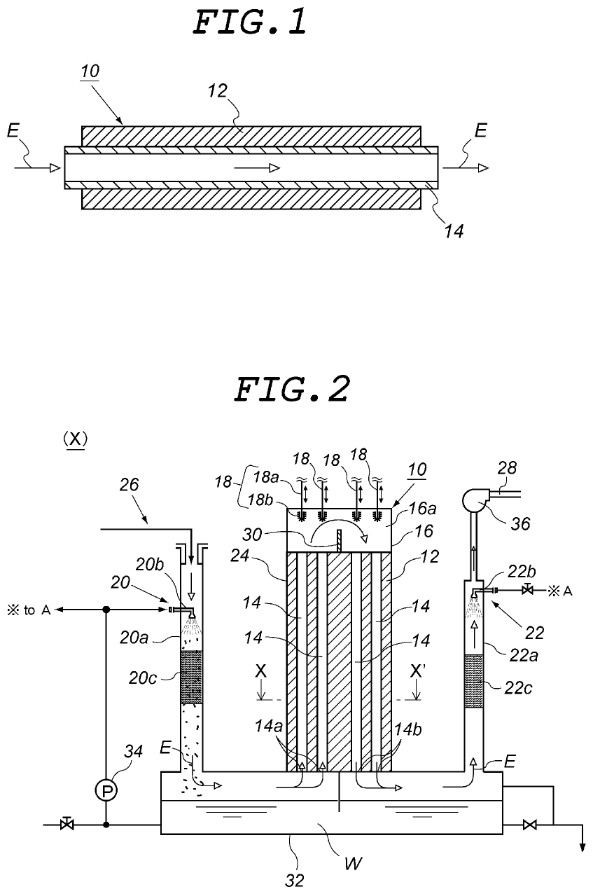

FIG. 1 is a sectional view schematically showing the most basic configuration (first embodiment) of a gas processing furnace 10 according to the present invention. As shown in FIG. 1, the gas processing furnace 10 of the present invention includes a heater body 12 and a tubular gas passage 14 passing through the heater body 12.

The heater body 12 is configured by filling, with an electric heating element, a casing made of, for example, a highly heat-resistant material such as metal like stainless steel and Hastelloy (registered trademark of Haynes International), or a refractory material such as a castable refractory material, and formed so as to surround an outer circumference of the gas passage 14 over the almost entire length thereof. Examples of the electric heating element include an element formed of metal wires such as a nichrome wire and Kanthal (registered trademark of Sandvik AB) wire, and an element formed of ceramic such as silicon carbide (SiC), molybdenum disilicide (MoSi₂), and lanthanum chromite (LaCrO₃). The element is selected as appropriate according to the temperature (heat amount) and the like required for the gas processing furnace 10.

Although not shown, an end portion of the electric heating element of the heater body 12 is led to the outside from, for example, a side face in an end portion, in the longitudinal direction, of the casing, and is connected to a power-supply device (not shown).

The gas passage 14 is made of, for example, a highly heat-resistant material such as metal like stainless steel and Hastelloy (registered trademark of Haynes International), or a refractory material such as a castable refractory material, and is a tubular member in which a heat-treatment-target gas flows. In the embodiment in FIG. 1, the sectional shape of the gas passage 14 in the width direction is a perfect circular shape, and the diameter and length thereof are set as appropriate according to a flow rate of the heat-treatment-target gas that flows in the gas passage 14. For example, when the gas processing furnace 10 shown in FIG. 1 is used for an abatement process of an exhaust gas E discharged from a semiconductor manufacturing apparatus, the diameter of the gas passage 14 is preferably set in a range of 80 mm to 150 mm, and the length thereof is preferably set in a range of 700 mm to 800 mm.

In the gas processing furnace 10 configured as described above according to the present embodiment, heat generated by the electric heating element can be applied fully and sufficiently to the gas flowing in the gas passage 14, in a case where the electric heating element to be used for the heater body 12 is selected according to the type of the heat-treatment-target gas flowing in the gas passage 14 and the diameter and the length of the gas passage 14 are set according to a flow rate of the heat-treatment-target gas.

Although not shown, the gas passage 14 is preferably provided with dust eliminating means for scraping dust and the like adhered/accumulated therein, as described below.

In the embodiment in FIG. 1, the gas passage 14 is arranged so as to cause the heat-treatment-target gas such as the exhaust gas E to flow in the horizontal direction. However, the flowing direction of the heat-treatment-target gas in the gas processing furnace 10 is not limited thereto, and the gas passage 14 may be arranged so as to cause the gas to flow in the up-down direction, for example.

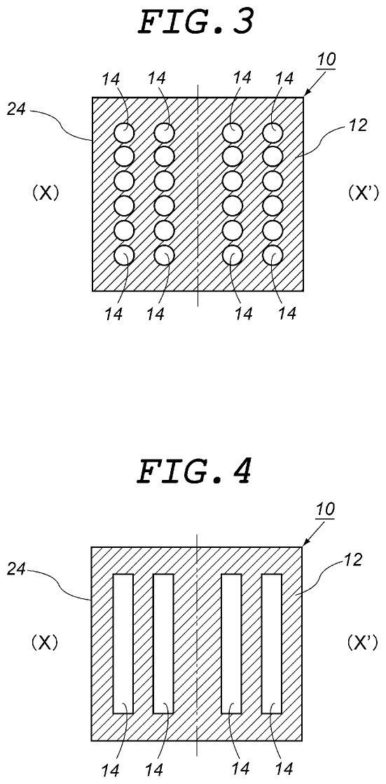

Subsequently, an exhaust gas processing device X according to one embodiment of the present invention will be described with reference to FIG. 2 and FIG. 3.

FIG. 2 schematically illustrates the exhaust gas processing device X in which a gas processing furnace 10 is used, according to a second embodiment of the present invention. The exhaust gas processing device X is a device that abates an exhaust gas E discharged from an exhaust source, which is not shown, and generally includes the gas processing furnace 10, an inlet scrubber 20, and an outlet scrubber 22.

Although the type of the processing-target exhaust gas E is not limited, the exhaust gas processing device X is particularly suitable for an abatement process of hardly decomposable exhaust gases E, having the specified emission standard, such as perfluoro compounds (PFCs), monosilane (SiH₄), and a chlorine-based gas that are discharged from a semiconductor manufacturing apparatus. Accordingly, the exhaust gas processing device X will be described below as an exhaust gas processing device used for an abatement process of the exhaust gas E discharged from a semiconductor manufacturing apparatus.

The gas processing furnace 10 is a device that thermally decomposes noxious abatement-target gases in the exhaust gas E exhausted through semiconductor manufacturing process or the like by an electrothermal oxidative decomposition method. The gas processing furnace 10 includes a heater body 12, a gas passage 14, and a headbox 16.

The heater body 12 includes a block-like body casing 24 that extends in the up-down direction and is obtained by forming, for example, a highly heat resistant material such as metal like stainless steel and Hastelloy (registered trademark of Haynes International) into a quadrangular-tube-like shape. Although not shown, an electric heating element made of metal wires such as a nichrome wire and Kanthal (registered trademark of Sandvik AB) wire, or ceramic or the like such as silicon carbide (SiC), molybdenum disilicide (MoSi₂), and lanthanum chromite (LaCrO₃) is extended (filled) over inside the body casing 24. In addition, gaps in the electric heating element are filled with ceramic powder, thereby improving the heat conductivity inside the body casing 24.

Although not shown, the end portion of the electric heating element is led to the outside from, for example, a lower face or a side face of the body casing 24 and is connected to the power-supply device.

The body casing 24 is provided with a plurality of the gas passages 14 passing through the inside thereof in the up-down direction.

Similarly to the body casing 24, the gas passages 14 are demarcated by, for example, a highly heat resistant material such as metal like stainless steel and Hastelloy (registered trademark of Haynes International), and are each formed as a narrow tube having a perfect circular shape in a plan view as shown in FIG. 3. In this way, the gas passages 14 each have a perfect circular shape in a plan view, and thus thermal stress can be dispersed without concentrating on a specific part of a tube wall of the gas passage 14 during operation and the like of the gas processing furnace 10, thereby effectively restraining the deformation and the like of the gas passage 14.

While the gas passages 14 having the same shape in a plan view are consecutively disposed in the front-back direction, the gas passages 14 consecutively disposed in such a manner are arranged so as to form a plurality of arrays parallel to each other in the right-left direction (four arrays are arranged in the illustrated embodiment, but two or three arrays, or five or more arrays may be arranged). The headbox 16 is mounted at an upper end portion of the body casing 24 having the gas passages 14.

Similarly to the body casing 24 or the like, the headbox 16 is a rectangular container body made of, for example, a highly heat resistant material such as metal like stainless steel and Hastelloy (registered trademark of Haynes International), and having an opened lower face. The headbox 16 is attached to the upper end portion of the body casing 24, and thus the gas passages 14 communicate with each other via a communication space 16a formed inside the headbox 16. In the embodiment in FIG. 2, the communication space 16a functions as a gas processing space.

In the gas processing furnace 10 of the embodiment shown in FIG. 2, the gas passages 14 are arranged so as to form four arrays. Among the four arrays, the two arrays on the left side in FIG. 2 are passages for supplying the processing-target exhaust gas E to the communication space 16a, and the two arrays on the right side in FIG. 2 are passages for exhausting the exhaust gas E having passed through the communication space 16a, from the gas processing furnace 10. Accordingly, the lower end openings of the gas passages 14 in the above-described two arrays on the left side are gas introduction ports 14a, and lower end openings of the gas passages 14 in the above-described two arrays on the right side are gas exhaust ports 14b, in a bottom face of the body casing 24.

In addition, the above-described gas introduction ports 14a are connected to a front end (upstream end) of an inflow tube system 26 that has the downstream end connected to an exhaust gas generation source such as a semiconductor manufacturing apparatus and that supplies the exhaust gas E into the communication space 16a, and the gas exhaust ports 14b are connected to a rear end (downstream end) of an exhaust tube system 28 that exhausts the exhaust gas E thermally decomposed in the gas processing furnace 10, to the atmosphere.

In addition, between the gas passage 14 in the second array from the left and the gas passage 14 in the second array from the right in a ceiling surface of the body casing 24, a partition wall 30 for increasing residence time of the exhaust gas E delivered to the communication space 16a is disposed.

Furthermore, right above the gas passages 14 in the headbox 16, dust eliminating means 18 each of which includes a shaft 18a and a brush 18b mounted at the end of the shaft 18a and is movable forward and backward in the gas passage 14 to scrape dust and the like adhered/accumulated in the gas passage 14, are provided. The dust eliminating means 18 is not limited to the above-described one, and may be, for example, one using an air-blow method.

Although not shown, for example, temperature measurement means composed of a thermocouple or the like for detecting the temperature of the communication space 16a is mounted in the gas processing furnace 10 of the present embodiment, and the temperature data (temperature signal) detected by the temperature measurement means is provided via a signal line to control means composed of a central processing unit (CPU), a memory, an input device, a display device, and the like. The above-described power-supply device is also connected to the control means.

In addition, the surface of the gas processing furnace 10 is covered with a jacket made of a heat insulating material, a refractory material, or the like as necessary (the same also applies to the above-described gas processing furnace 10 in the first embodiment).

The gas processing furnace 10 configured as described above according to the present embodiment is installed so as to stand on a storage tank 32 described below.

The inlet scrubber 20 is for eliminating dust, water-soluble components, and the like contained in the exhaust gas E to be introduced into the gas processing furnace 10, and includes a straight tube type scrubber body 20a, a spray nozzle 20b that is installed in the vicinity of the top of the scrubber body 20a in the scrubber body 20a and that sprays a chemical liquid such as water in an atomized state, and a filling material 20c for promoting gas-liquid contact between the exhaust gas E and the chemical liquid sprayed from the spray nozzle 20b.

The inlet scrubber 20 is provided at a location in the inflow tube system 26, and installed so as to stand on the storage tank 32 that stores therein the chemical liquid such as water.

A circulation pump 34 is installed between the spray nozzle 20b and the storage tank 32 so as to raise the chemical liquid stored in the storage tank 32 up to the spray nozzle 20b.

The outlet scrubber 22 is for cooling the thermally-decomposed exhaust gas E that has passed through the gas processing furnace 10, and finally eliminating dust, water-soluble components, and the like produced as a byproduct through thermal decomposition, from the exhaust gas E. The outlet scrubber 22 includes a straight tube type scrubber body 22a, a downward-oriented spray nozzle 22b that is installed in the vicinity of the top of the scrubber body 22a in the scrubber body 22a and that sprays a chemical liquid such as water from the upper side in the direction opposite to the flowing direction of the exhaust gas E, and a filling material 22c for promoting gas-liquid contact between the exhaust gas E and the chemical liquid sprayed from the spray nozzle 22b.

The outlet scrubber 22 is provided at a location in the exhaust tube system 28, and installed so as to stand on the storage tank 32 that stores therein the chemical liquid such as water.

Similarly to the above-described inlet scrubber 20, the circulation pump 34 is installed between the spray nozzle 22b and the storage tank 32 so as to raise the chemical liquid stored in the storage tank 32 up to the spray nozzle 22b in the illustrated embodiment. However, instead of the chemical liquid stored in the storage tank 32, another chemical liquid may be supplied, for example, water may be supplied anew, to the spray nozzle 22b.

An exhaust fan 36 for discharging the processed exhaust gas E to the atmosphere is connected onto the exhaust tube system 28 in the vicinity of an outlet at the top of the outlet scrubber 22.

Corrosion-resistant lining or coating is applied, using vinyl chloride, polyethylene, unsaturated polyester resin, fluororesin, or the like, to parts other than the gas processing furnace 10 of the exhaust gas processing device X according to the present embodiment, to protect each part from corrosion due to corrosive components such as hydrofluoric acid contained in the exhaust gas E or produced by decomposition of the exhaust gas E.

Subsequently, when the exhaust gas E is abated using the exhaust gas processing device X configured as described above, an operation switch (not shown) of the exhaust gas processing device X is firstly turned on to operate the electric heating element of the gas processing furnace 10, thereby starting heating inside the gas processing furnace 10.

When the temperature inside the communication space 16a reaches a predetermined temperature, in a range of 800° C. to 1400° C., corresponding to the type of the processing-target exhaust gas E, the exhaust fan 36 operates to start introduction of the exhaust gas E into the exhaust gas processing device X. Then, the exhaust gas E passes through the inlet scrubber 20, the gas processing furnace 10, and the outlet scrubber 22 in this order, to abate abatement-target components in the exhaust gas E. In addition, the control means, which is not shown, controls the amount of power to be supplied to the electric heating element of the gas processing furnace 10 so as to maintain a predetermined temperature inside the communication space 16a.

In the exhaust gas processing device X of the present embodiment, the gas passages 14 that pass through the heater body 12 in the gas processing furnace 10 in the up-down direction, are each formed as a narrow tube having a perfect circular shape in a plan view, thereby applying heat generated by the electric heating element to the whole processing-target gas flowing in the gas passages 14 without waste. In addition, the gas passages 14 are arranged so as to form four arrays parallel to each other in the right-left direction in a plan view, and two arrays are provided on each of an inlet side and an outlet side, thereby increasing a flow rate of the gas on which heat treatment can be performed.

In addition, in the exhaust gas processing device X of the present embodiment, since the inlet scrubber 20 and the outlet scrubber 22 are provided, clogging and the like in the inflow tube system 26 can be prevented by previously washing, with liquid, the exhaust gas E to be introduced into the gas processing furnace 10, and cleanliness of the exhaust gas E thermally decomposed can be improved, while the gas processing furnace 10 can be continuously operated more stably.

The above described embodiments shown in FIG. 2 and FIG. 3 can be modified as follows.

Specifically, in the above-described gas processing furnace 10 in the second embodiment, the gas passages 14 each formed as a narrow tube having a perfect circular shape are consecutively disposed in the front-back direction in a plan view. However, as shown in FIG. 4, each gas passage 14 may be, for example, formed in an elongated slit shape extending in the front-back direction, and the gas passages 14 extending so as to have the same slit shape may be disposed in a plurality of arrays (four arrays in the embodiment in FIG. 4) parallel to each other in the right-left direction, in a plan view. The gas passage 14 having such a shape is inferior, in the performance of dispersing thermal stress during operation and the like of the gas processing furnace 10, to the gas passage formed in a perfect circular shape in a plan view as described above. However, such a shape allows the gas processing furnace 10 to be economically and efficiently manufactured.

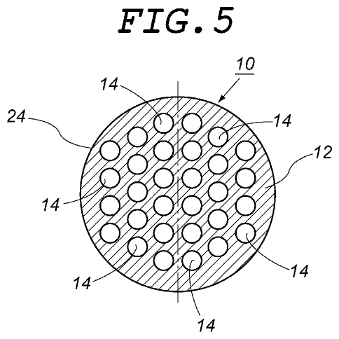

In addition, in the above-described gas processing furnace 10 in the second embodiment, the body casing 24 of the heater body 12 is shaped in a quadrangular tube. However, the shape of the body casing 24 is not limited thereto, and the body casing 24 may be, for example, formed as a cylindrical body having a perfect circular shape in a plan view as shown in FIG. 5, similarly to the gas passage 14. In this case, the body casing 24 itself can also serve to improve the performance of dispersing thermal stress during operation and the like of the gas processing furnace 10.

Furthermore, in the exhaust gas processing device X in the above-described embodiment, the configuration in which the gas passages 14 of the gas processing furnace 10 are arranged so as to form four arrays parallel to each other in the right-left direction in a plan view, and the two arrays are provided on each of the inlet side of the communication space 16a and the outlet side of the communication space 16a, is shown. However, the passage for the gas inside the heater body 12 is not limited thereto, and may be, for example, configured to allow the processing-target gas to be directly supplied into the communication space 16a of the headbox 16 according to the nature and the like of the processing-target gas, and allow the gas to pass (flow down) through the whole gas passage 14 in one go.

In the exhaust gas processing device X of the above-described embodiment, both the inlet scrubber 20 and the outlet scrubber 22 are provided. However, either one of the inlet scrubber 20 and the outlet scrubber 22 may be provided according to the type of the exhaust gas E to be processed. In addition, the inlet scrubber 20 and the outlet scrubber 22 are installed so as to stand on the storage tank 32. However, the inlet scrubber 20 and the outlet scrubber 22 may be arranged separately from the storage tank 32 and connected to the storage tank 32 via piping to deliver drainage from each of the scrubbers 20 and 22 to the storage tank 32.

### INDUSTRIAL APPLICABILITY

The exhaust gas processing device of the present invention not only can thermally decompose various kinds of processing-target exhaust gases assuredly but also has extremely high processing efficiency, provides very excellent safety, and can be downsized. Therefore, the exhaust gas processing device of the present invention can be used for not only thermal decomposition of the exhaust gas exhausted through the above-described semiconductor manufacturing process, but also decomposition of the exhaust gas exhausted through any industrial process, for example, heat treatment of the exhaust gas in chemical plants. In addition, the gas processing furnace of the present invention can be used for not only thermal decompositions of the exhaust gas but also heat treatment of various gases in industrial processes.

### REFERENCE SIGNS LIST

10 gas processing furnace

12 heater body

14 gas passage

16 headbox

16a communication space

18 dust eliminating means

20 inlet scrubber

22 outlet scrubber

E exhaust gas

X exhaust gas processing device

1. A gas processing furnace comprising:
a heater body filled with an electric heating element; and
a tubular gas passage passing through the heater body.

2. A gas processing furnace comprising:
a block-like heater body extending in an up-down direction and filled with an electric heating element;
gas passages passing through the heater body in the up-down direction, the gas passages being consecutively disposed or extended in a front-back direction, the gas passages being arranged so as to form a plurality of arrays parallel to each other in a right-left direction, in a plan view; and
a headbox mounted at an upper end portion of the heater body and configured to allow the gas passages to communicate with each other via a communication space formed inside the headbox.

3. The gas processing furnace according to claim 1, wherein the gas passage is formed as a narrow tube having a perfect circular shape in a plan view.

4. The gas processing furnace according to claim 1, wherein the gas passage is formed in an elongated slit shape in a plan view.

5. The gas processing furnace according to claim 1, wherein dust eliminating means for eliminating dust accumulated in the gas passages is provided.

6. An exhaust gas processing device comprising:
the gas processing furnace according to claim 1; and
at least one of an inlet scrubber for previously washing, with liquid, a processing-target exhaust gas to be introduced into the gas processing furnace, and an outlet scrubber for cooling an exhaust gas thermally decomposed in the gas processing furnace and washing the exhaust gas with liquid.
